(19) United States
(12) Patent Application Publication
(10) Pub. No.: US 2024/0379415 A1
(43) Pub. Date: Nov. 14, 2024

(54) CONTACT FOR ELECTRONIC COMPONENT

(71) Applicant: STMicroelectronics International N.V., Geneva (CH)

(72) Inventors: Pascal Fornara, Pourrières (FR); Christian Rivero, Peynier (FR); Julien Amouroux, Aix en Provence (FR); Antonin Chollet, Rousset (FR)

(21) Appl. No.: 18/659,205

(22) Filed: May 9, 2024

(30) Foreign Application Priority Data
May 12, 2023 (FR) 2304734

(51) Int. Cl. H01L 21/768; H01L 23/522; H01L 23/532

(52) U.S. Cl. CPC H01L 21/76831; H01L 21/76802; H01L 21/76843; H01L 21/76883; H01L 23/5226; H01L 23/53238; H01L 23/53266; H01L 23/5329

(57) ABSTRACT

The present disclosure relates to a method for manufacturing a contact on a semiconductor region of an electronic component. The method includes forming a coating layer of dielectric material, with a thickness, on at least one side wall of an opening crossing through a dielectric region of the electronic component along a longitudinal direction from a first surface of the dielectric region, and opening out at the semiconductor region. The method includes forming of a metal filler layer, so as to fill the opening coated with the coatin

### CROSS-REFERENCE TO RELATED APPLICATIONS

This application claims priority to French Patent Application No. 2304734, filed on May 12, 2023, which application is hereby incorporated herein by reference.

### TECHNICAL FIELD

The present disclosure relates generally to electronic devices and more particularly to electronic components comprising semiconductors.

### BACKGROUND

In an electronic device such as an integrated circuit, electronic components are coupled together by electrically conductive connections and thereby form electronic circuits. More particularly, certain electronic components such as transistors, diodes, etc. comprise semiconductor regions electrically coupled to the conductive connections. Typically, a transistor, e.g. of the MOS type, comprises such drain and source semiconductor regions. For each of said semiconductor regions, the electrical coupling with the conductive connections is provided by a contact, also referred to by the term “electrical contact”, or “contact”, i.e. an electrically conductive region in contact with the semiconductor region.

For example, the electrical contact is connected both to the semiconductor region and to a first metal level of an interconnection region, known by a person skilled in the art under the acronym BEOL (Back End of Line).

### SUMMARY

One embodiment addresses all or some of the drawbacks of electrical contacts for an electronic component.

One embodiment addresses all or some of the drawbacks of the known methods for manufacturing electrical contacts on semiconductor regions of an electronic component.

One embodiment provides a manufacturing method making it possible to adapt the cross-section, or a transverse dimension, e.g. the diameter, of one or a plurality of electrical contacts, e.g. for the same manufacturing line.

A particular embodiment provides a manufacturing method making it possible to reduce the cross-section, or a transverse dimension, e.g. the diameter, of one or a plurality of electrical contacts.

One embodiment provides a method for manufacturing a contact on a semiconductor region of an electronic component, the method comprising: the formation of a coating layer of dielectric material, with a given thickness, on at least one side wall of an opening crossing through a dielectric region of the electronic component along a longitudinal direction from a first surface of said dielectric region, and opening out at the semiconductor region; then the formation of a metal filler layer, so as to fill the opening coated with the coating layer.

According to one embodiment, the opening has a given, for example fixed, cross-section, and the thickness is determined for adapting the effective cross-section of the contact by reducing the cross-section of the opening.

According to one embodiment, the opening has a circular cylinder shape with a given, for example fixed, first diameter, the contact has a circular cylinder shape with a second diameter smaller than the first diameter, and the thickness is determined for adapting the second diameter by reducing the first diameter by at least twice said thickness.

According to one embodiment, the formation of the coating layer comprises: the deposition of a layer of dielectric material from the first surface of the dielectric region, at least on the side walls and at the bottom of the opening; and the removal by etching of a portion of the layer of dielectric material located at the bottom of the opening.

According to one embodiment, the removal by etching further comprises the removal of a portion of the dielectric material layer located on the first surface of the dielectric region.

According to one embodiment, the etching is an anisotropic plasma etching, suitable for etching the layer of dielectric material preferentially along the longitudinal direction.

According to one embodiment, the method further comprises the formation of a diffusion barrier layer at the bottom of the opening and laterally in said opening on the coating layer, the formation of the diffusion barrier layer being carried out after the formation of the coating layer and before the formation of the filler layer.

According to one embodiment, the formation of the metal filler layer comprises: the deposition of a metal layer from the first surface of the dielectric region; then the removal of a portion of the metal layer extending over the openings and the first surface of the dielectric region, so as to make the contact flush with the first surface.

According to one embodiment, the removal includes a planarization, for example a chemical mechanical polishing.

One embodiment provides an electronic component comprising at least one contact on a semiconductor region of said electronic component, each contact being positioned in an opening crossing through a dielectric region of the electronic component along a longitudinal direction from a first surface of said dielectric region, and opening out at the semiconductor region, said contact comprising a coating layer of dielectric material, with a given thickness, extending along at least one side wall of the opening and a metal filler layer in the opening coated with the coating layer.

According to one embodiment, the electronic component further comprises a diffusion barrier layer at the bottom of the opening and laterally in said opening between the coating layer and the filler layer.

According to one embodiment, the electronic component further comprises a gas cavity, for example an air cavity, crossing through an interconnection region of the electronic component and the dielectric region, for example near the contact.

According to one embodiment: the dielectric material of the coating layer, or of the layer of dielectric material, is chosen from one or a plurality of materials among: silicon nitride, silicon oxide, a low dielectric constant material, such as silicon oxycarbide, silicon oxycarbonitride, or silicon carbonitride; and/or the metal of the filler layer, or of the metal layer, is chosen among tungsten or copper.

According to one embodiment, the thickness of the coating layer is greater than or equal to 20 nm, for example greater than or equal to 50 nm.

According to one embodiment, the electronic component comprises at least one MOS transistor arranged in and on a substrate, the semiconductor region being a drain region, a source region, or even a gate region of said transistor.

According to one embodiment, the electronic component comprises a silicide interface layer suitable for forming an interface between the semiconductor region and the contact.

One embodiment provides for an electronic device comprising at least one electronic component as described hereinabove.

According to one embodiment, the electronic device is a radio frequency signal switch.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, FIG. 1D, FIG. 1E and FIG. 1F are sectional views representing structures obtained at the end of steps of an example of method for manufacturing an electrical contact for an electronic component;

FIG. 2A, FIG. 2B, FIG. 2C, FIG. 2D and FIG. 2E are sectional views representing structures obtained at the end of steps of a method for manufacturing an electrical contact for an electronic component according to one embodiment;

FIG. 3A and FIG. 3B are sectional views representing contacts of an electronic component according to embodiments; and

FIG. 4A and FIG. 4B are sectional views schematically representing examples of electronic components to which the embodiments apply.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the manufacturing steps and the details of the elements of the electronic components, other than the contacts concerned by the embodiments, e.g. the drain, the source, the channel and the gate regions for a MOS transistor, are not discussed in detail, since same can be carried out with the usual methods for manufacturing electronic components. Furthermore, the manufacturing steps and the details of the interconnection regions are not discussed in detail, since same can be carried out with the usual methods of manufacturing electronic components.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures or to an electronic component as orientated during normal use.

Unless specified otherwise, the expressions “around”, “approximately”, “substantially” and “in the order of” signify within 10%, and preferentially within 5%.

In the following description, when reference is made to a contact, same should be understood as an electrical contact for an electronic component.

In the following description, when referring to the longitudinal direction of a contact or of an opening, it should be understood the direction along which the contact or opening crosses through a dielectric region for connecting a semiconductor region of an electronic component, or, in other words, the direction corresponding to the depth of the contact or of the opening in the dielectric region. A side wall of an opening corresponds to a wall extending along the longitudinal direction. A transverse direction corresponds to a direction in a plane transverse to the longitudinal direction. A transverse plane can correspond to the plane of a section of the contact or of the opening. A transverse dimension corresponds to a dimension taken along a transverse direction. According to one example, a transverse dimension is a diameter, but is not limited to.

In the following description, the effective diameter of an electrical contact refers to the metal diameter of the contact. More broadly, an effective transverse dimension of an electrical contact refers to the metal dimension of the contact along the considered transverse direction. In other words, the effective cross-section of an electrical contact refers to the metal cross-section of the contact.

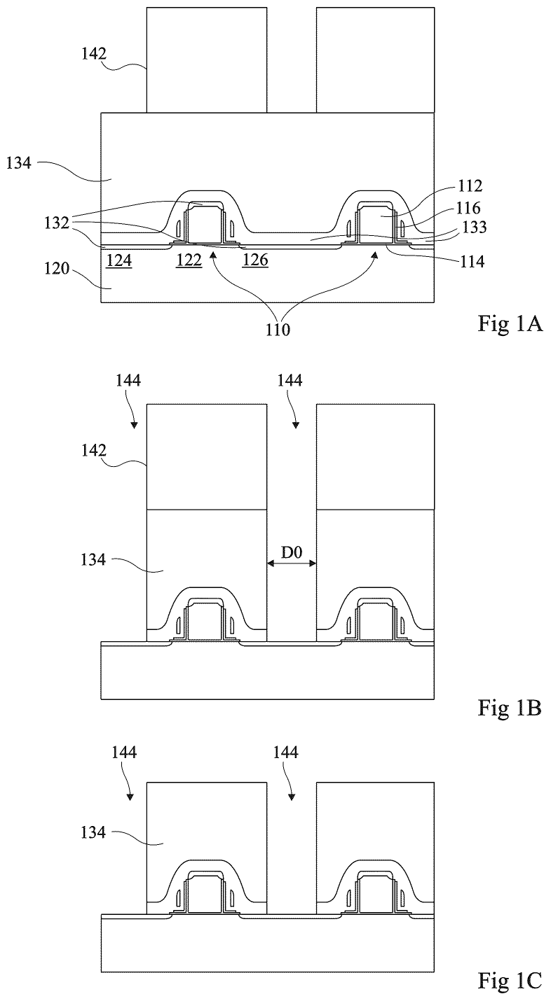

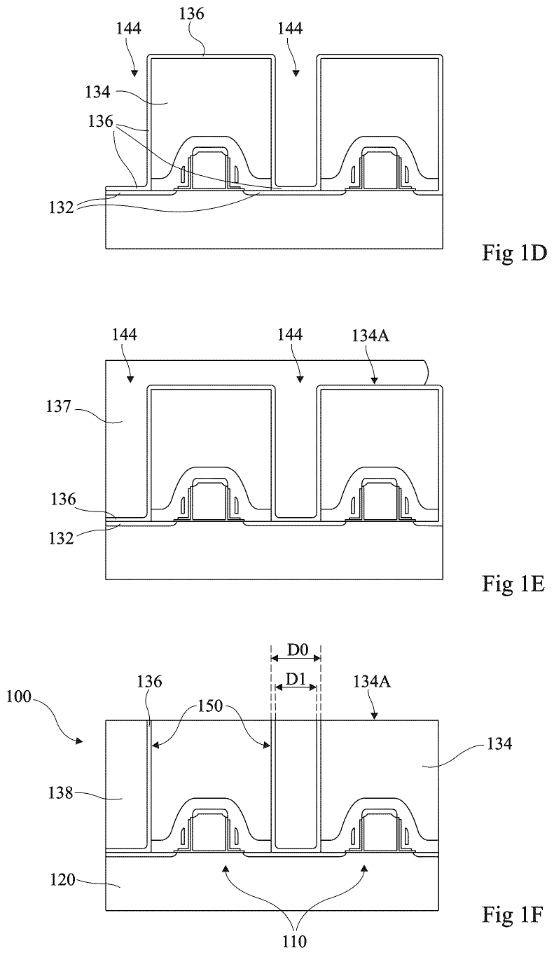

FIG. 1A, FIG. 1B, FIG. 1C, FIG. 1D, FIG. 1E and FIG. 1F are sectional views representing structures obtained at the end of steps of an example of a method for manufacturing an electrical contact 150 for an electronic component 100.

The longitudinal direction corresponds substantially, in the structures shown, to a direction perpendicular to the substrate.

FIG. 1A shows a starting structure wherein the electronic component comprises two MOS transistors 110. Each transistor 110 is formed in and on a substrate 120. The substrate 120 is a semiconductor, preferentially made of silicon.

Each transistor 110 comprises a gate region 112 covering a channel-formation region, or channel, 122 in the substrate 120. The channel-formation region 122 is located between two doped semiconductor regions of the substrate 120, forming the drain region 124 and the source region 126, respectively, of the transistor 110, or the source region 124 and the drain region 126 of the transistor 110. The gate region 112 is generally made of polysilicon, or polycrystalline silicon. The gate region 112 is isolated from the channel 122 by a gate oxide layer 114, and flanked by an insulating lateral region, or spacer, 116.

The electrical contacts 150, represented in FIG. 1F, are used for coupling these semiconductor regions 124, 126 to an interconnection region (not shown in FIGS. 1A to 1F).

It can also be provided the forming of a metal silicide layer or silicide layer, 132 at the interface between the semiconductor region 122, 124 and the contact 150. Such a silicide layer significantly reduces the value of the electrical access resistance of the contact, i.e. the resistance between the semiconductor region and the contact. In the example illustrated in FIG. 1A, the drain, the source and the gate regions each have a metal silicide layer 132 on top.

For example, in order to form a metal silicide layer 132, it is possible, after an annealing of the concerned semiconductor region, to protect with a mask the regions which are not to be silicided, to deposit a cobalt/titanium nitride (Co/TiN) bilayer, then to carry out a first rapid heat treatment, typically at about 530° C. for a few seconds, so as to form cobalt mono-silicide (CoSi), then to remove the Co/TiN bilayer, and to carry out a densification annealing, typically at about 800° C. for a few seconds, which leads to converting the CoSi into cobalt di-silicide (CoSi₂) forming the silicide layer 132 on the semiconductor region.

Furthermore, as illustrated in FIG. 1A, an etch stop layer 133, typically made of silicon nitride (Si₃N₄), can be deposited above the drain, the source and the gate regions, in particular can be formed on the silicide layers 132. The etch stop layer 133 can be used as a stop layer during the manufacture of the contacts 150.

Then, as illustrated in FIG. 1A, a region made of a dielectric material 134 (dielectric region), e.g. a dielectric material known by the person skilled in the art under the acronym PMD, standing for pre-metal dielectric, can be formed on the etch stop layer 133. According to one example, the PMD is a variably doped silicon dioxide (SiO₂).

As illustrated in FIG. 1A, an etching mask 142 is then formed on the dielectric region 134, e.g. by using a photolithography technique, the etching mask comprising openings at the location of the future electrical contacts.

FIG. 1B shows a structure obtained after an etching of openings 144 in the dielectric region 134 through the etching mask 142.

Preferentially, each opening 144 crosses through the stop layer 133 and stops at the silicide layer 132.

For example, each opening 144 is substantially cylindrical and has a diameter Do (first diameter).

FIG. 1C represents a structure obtained at the end of the elimination of the etching mask 142.

FIG. 1D represents a structure obtained after the deposition of a diffusion barrier layer 136, e.g. a titanium/titanium nitride (Ti/TiN) bilayer, over the structure of FIG. 1C. The Ti layer can form an adhesion layer and the TiN layer can form the diffusion barrier layer.

The diffusion barrier layer 136 thereby covers the etched dielectric region 134, the side walls of each opening 144 and the silicide layer 132 at the bottom of each opening 144.

Such deposition of a layer/bilayer can e.g. be carried out using a chemical vapor deposition technique known by the acronym CVD (Chemical Vapor Deposition), or a physical vapor deposition technique known by the acronym PVD (Physical Vapor Deposition), or a technique of atomic layer deposition, known by the acronym ALD (Atomic Layer Deposition).

FIG. 1E represents a structure obtained after depositing a metal layer 137, e.g. tungsten (W), over the diffusion barrier layer 136. In particular, the metal layer 137 fills the openings 144.

FIG. 1F represents a structure obtained at the end of a step of removing portions of the diffusion barrier layer 136 and of the metal layer 137 extending above the openings 144 and above the upper surface 134A of the dielectric region 134, so as to form in each opening, a metal filler layer 138, and thereby metal contacts 150, flush with the upper surface 134A of the dielectric region 134. Such step of removal, or of planarization, can be carried out in a conventional manner by chemical mechanical polishing, known by the acronym CMP (Chemical Mechanical Polishing).

An electronic component 100 is thereby obtained, which comprises electrical contacts 150 coupled to drain 124 and source 126 regions of the MOS transistors 110, via a silicide layer 132.

For example, the effective diameter D1 of each electrical contact 150 is about 200 nm.

Due to the thickness of the diffusion barrier layer 136, the effective diameter D1 of each electrical contact 150 is smaller than the diameter Do of each opening 144.

The thickness of the diffusion barrier layer 136 can depend on the diameter Do of the opening 144. For example, the diameter Do of each opening 144 can be calibrated at about 260 nm, for an effective contact diameter D1 of about 200 nm, and the diffusion barrier layer 136 can have an average thickness of about 30 nm. For example, the diffusion barrier layer 136 comprises a Ti layer having an average thickness of about 25 nm, and a TiN layer having an average thickness of about 5 nm or 6 nm.

For example, if the deposition of the diffusion barrier layer 136 is an ALD deposition, the thickness of the diffusion barrier layer can be substantially uniform and can be less than 30 nm. If the deposition of the diffusion barrier layer 136 is a CVD or a PVD, the thickness of the diffusion barrier layer can be greater above the etched dielectric region 134 than on the side walls and at the bottom of the opening 144.

Due to constraints of the manufacturing method, and in particular cost constraints, the diameter Do of the openings is generally fixed. For example, the openings are manufactured during the same photolithography and etching step of a manufacturing line. Furthermore, the thickness of the diffusion barrier layer is generally also fixed, e.g. because of the deposition techniques used. Thereby, it is generally not easy to modify the effective diameter of the metal contacts, in particular without modifying the photolithography and etching step in a manufacturing line. For example, changing the diameter of the openings could require changing the photolithography techniques and/or the parameters (e.g. changing the equipment, the etching mask, and/or the photoresist), and/or changing the etching techniques and/or the parameters (e.g. changing the etching equipment) which can lead to additional costs or even a waste of time during such changes. A more advanced technological node could be involved, which could imply the need for more efficient equipment, generally more expensive.

The inventors propose a contact on a semiconductor region of an electronic component and a method for manufacturing such a contact, making it possible to meet the needs for improvement, as described hereinabove, and to overcome all or part of the drawbacks of the contacts described hereinabove. More particularly, the inventors propose a contact and a method for manufacturing such a contact making it possible to adapt the cross-section, or a transverse dimension, e.g. the diameter, of one or a plurality of contacts, e.g. in the same manufacturing line.

Embodiments of contacts will be described hereinafter. The embodiments described are non-limiting and various variants will become apparent to a person skilled in the art, from the indications of the present description.

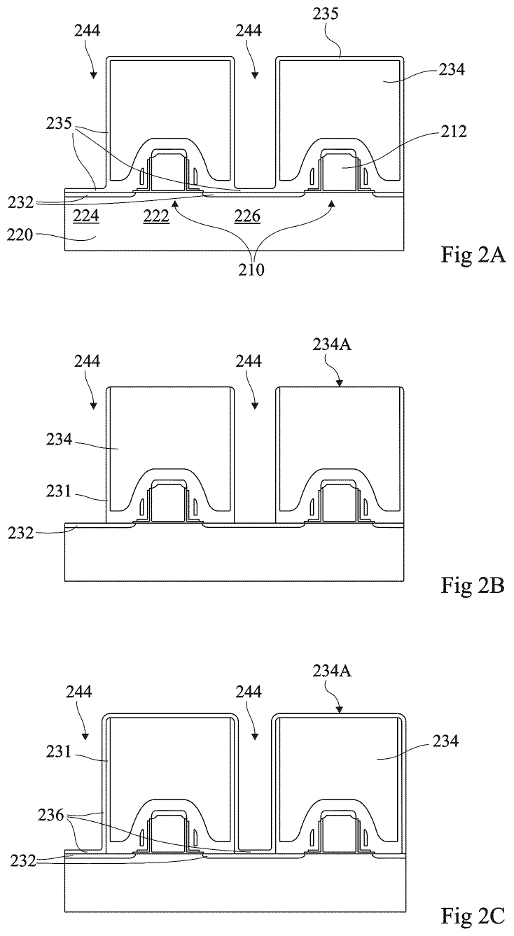

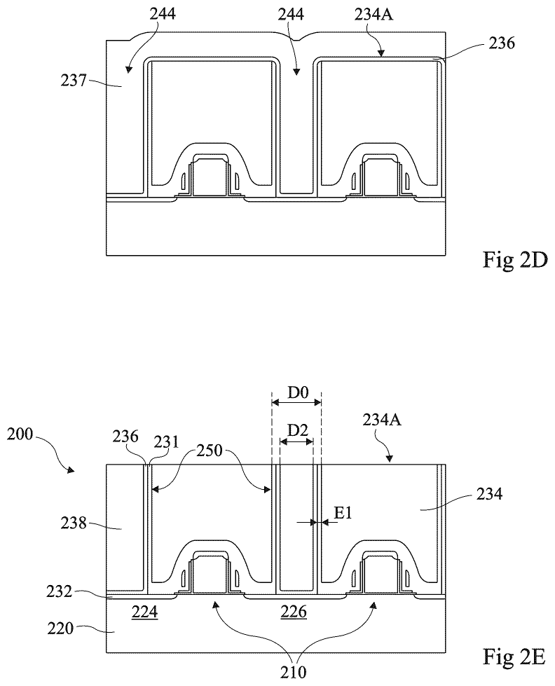

FIG. 2A, FIG. 2B, FIG. 2C, FIG. 2D and FIG. 2E are sectional views representing structures obtained at the end of steps of a method of manufacturing an electrical contact 250 for an electronic component 200 according to one embodiment.

The starting structure of the fabrication process described is a structure resulting from a fabrication process of openings crossing through a dielectric region, so as to define the location of future contacts on semiconductor regions, e.g. with prior formation of a silicide layer on the semiconductor regions. In the embodiments shown, the contacts are electrical contacts for MOS transistors 210, such as the MOS transistors 110 described with reference to FIG. 1A, the semiconductor regions being drain or source regions 224, source or drain regions 226, or even gate regions 212 of the MOS transistors. The channel-formation region 222 is located between the drain and source regions.

For example, the starting structure can be a structure resulting from a process similar to the process described with reference to FIGS. 1A, 1B and 1C, up to and including the step of etching the openings 244 in a dielectric region 234. The openings 244 come out onto a silicide layer 232 covering the semiconductor regions 224, 226.

In the embodiments shown, the longitudinal direction of the openings and of the contacts corresponds substantially to the vertical, but are not limited to.

FIG. 2A shows a structure obtained after depositing a layer of dielectric material 235 (dielectric layer) on the starting structure.

The dielectric material of the dielectric layer 235 can be silicon nitride (Si₃N₄), a silicon oxide (SiO₂), or a low-K material, i.e. a material with a lower dielectric constant than the dielectric constant of SiO₂, e.g. silicon oxycarbide (SiCO), silicon oxycarbonitride (SiOCN) or silicon carbonitride (SiCN).

Such deposition, which can be referred to as “conformal deposition”, can be carried out using a CVD technique or a PVD technique.

The dielectric layer 235 thereby covers the upper surface 234A (first surface) of the etched dielectric region 234, the side walls of each opening 244 and the silicide layer 232 at the bottom of each opening 244.

FIG. 2B shows a structure obtained after the removal by etching of the portion of the dielectric layer 235 which covers the silicide layer 232 at the bottom of each opening 244, and of the portion of the dielectric layer 235 which covers the upper surface 234A of the etched dielectric region 234, so as to leave at least the portion of the dielectric layer which covers the side walls of each opening 244, and thereby forming a coating layer 231 of dielectric material on said side walls.

Preferentially, the portion of the dielectric layer 235 which covers the silicide layer 232 at the bottom of each opening 244 is etched as far as the silicide layer 232.

In a variant, the portion of the dielectric layer 235 which covers the upper surface 234A of the dielectric region 234 is not etched during said etching.

The etching is preferentially a plasma etching, as anisotropic as possible, so as to etch the dielectric layer 235 preferentially along the longitudinal direction, and to prevent the etching of the portions of the dielectric layer 235 which cover the side walls of each opening 244. As an example, the plasma comprises carbon tetrafluoride (CF₄) or trifluoromethane (CHF₃). For example, the etching is a set-time etching, the time being determined for etching the thickness of the dielectric layer 235. In a variant, depending on the etching equipment used, the latter can be adapted to detect the end of the attack by etching.

FIG. 2C represents a structure obtained after the deposition of a diffusion barrier layer 236, e.g. a titanium/titanium nitride (Ti/TiN) bilayer, over the structure of FIG. 2B. The Ti layer can form an adhesion layer and the TiN layer can form the diffusion barrier layer.

As an example, the diffusion barrier layer 236 has an average thickness of about 30 nm. For example, the diffusion barrier layer 236 comprises a Ti layer with an average thickness of about 25 nm, and a TiN layer with an average thickness of about 5 or 6 nm.

The thickness of the diffusion barrier layer 236 can depend on the diameter Do of the opening 244.

Alternatively to a Ti/TiN bilayer, a single layer of TiN forming a diffusion barrier, a tantalum/tantalum nitride (Ta/TaN) bilayer, or any other layer or multilayer suitable for forming a diffusion barrier, could be used.

The layer/bilayer deposition can, e.g. be carried out using a CVD technique, or a PVD technique, or alternatively an ALD technique.

The diffusion barrier layer 236 thereby covers the upper surface 234A of the etched dielectric region 234, the side walls of each opening 244 covered with the coating layer 231 and the silicide layer 232 at the bottom of each opening 244.

FIG. 2D represents a structure obtained after the deposition of a metal layer 237, e.g. tungsten (W), over the structure of FIG. 2C. In particular, the metal layer 237 fills the openings 244. Alternatively to tungsten, the metal could be e.g. copper (Cu).

The deposition step can e.g. be carried out using a CVD technique or an ALD technique.

FIG. 2E represents a structure obtained at the end of a step of removing portions of the diffusion barrier layer 236 and of the metal layer 237 extending above the openings 244 and above the upper surface 234A of the dielectric region 234, so as to form in each opening a metal filler layer 238, and thereby metal contacts 250, flush with the upper surface 234A of the dielectric region 234. The removal, or planarization, step can be carried out conventionally by CMP (chemical mechanical polishing).

An electronic component 200 is thereby obtained, which comprises electrical contacts 250 coupled to the drain 224 and source 226 regions of the MOS transistors 210, via a silicide layer 232.

Furthermore, for an equal diameter Do (first diameter) of the opening 244 and for an equal thickness of the diffusion barrier layer 236, the effective diameter D2 (second diameter) of the contacts 250 is reduced with respect to the effective diameter D1 of the contacts 150 of the electronic component of FIG. 1F. In other words, for an equal opening diameter Do and for an equal thickness of the diffusion barrier layer, the addition of a coating layer 231 of dielectric material on the side walls of each opening 244 reduces the effective diameter D2 of each contact 250.

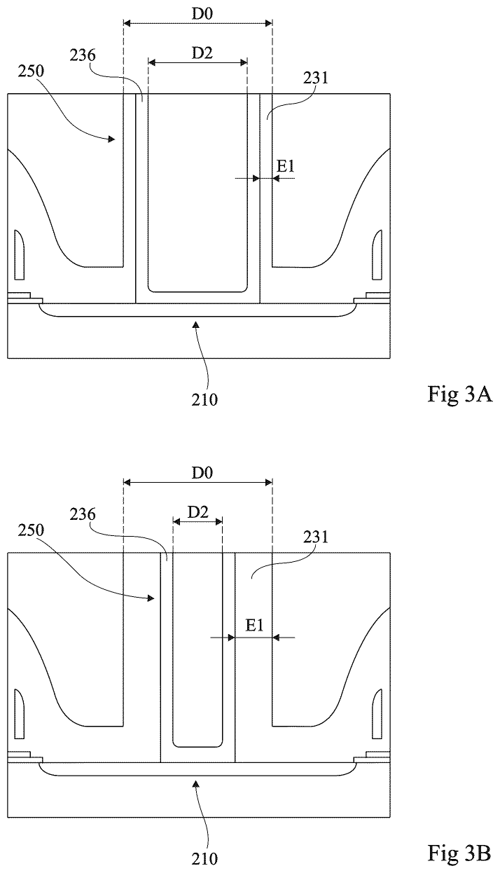

More generally, by adjusting the thickness E1 of the coating layer 231 deposited on the side walls of an opening 244, it is possible to adapt the effective diameter D2 of a contact 250 without having to modify the diameter Do of the opening, e.g. without having to modify the photolithography and etching steps for forming the openings. Hereinafter, FIGS. 3A and 3B illustrate examples of such adjustment.

FIGS. 3A and 3B are sectional views schematically representing contacts 250 of electronic components according to embodiments.

The contacts 250 of FIGS. 3A and 3B are similar to each other, and to the contacts of FIG. 2E, and only the thicknesses E1 of the coating layer 231 deposited on the side walls of the opening 244 change between FIGS. 3A and 3B, thereby varying the effective diameter D2 of the contact 250. For example, the diameter Do of each opening 244 is about 250 nm.

According to one example, in FIG. 3A, the thickness E1 of the coating layer 231 is equal to approximately 20 nm, and the effective diameter D2 of the contact 250 is equal to approximately 160 nm.

According to another example, in FIG. 3B, the thickness E1 of the coating layer 231 is equal to about 50 nm, and the effective diameter D2 of the contact 250 is equal to about 100 nm.

An advantage of the embodiments is that it makes it possible to reduce the effective cross-section of a contact, e.g. the effective diameter of the contact, without having to significantly modify the manufacturing method, e.g. without having to change the manufacturing line. Reducing the effective cross-section of a contact, e.g. the effective diameter of the contact, reduces the parasitic capacitance due to the presence of the contact, and thereby reduces the off-state capacitance, known as “Coff”, of the electronic component connected to the contact.

Another advantage of reducing the effective cross-section of a contact, e.g. the effective diameter of the contact, is that the distance from the contact to another semiconductor region of the electronic component, e.g. a gate region of a transistor, can be increased in this way, and thereby can improve the insulation of the contact with respect to the other semiconductor region.

Another advantage of reducing the effective cross-section of a contact, e.g. the effective diameter of the contact, by adding a dielectric layer on the side walls of the opening, is that the adjacent contacts are in this way insulated from each other, and the contacts can be brought closer together, and, consequently, more contacts can be formed for the same surface.

Another benefit of reducing the effective cross section of a contact, e.g. the effective diameter of the contact, is the ability of controlling the resistance R(Ω) of the contact, by acting on said effective cross section S(m²), according to the formula: R(Ω)=ρ(Ωm)×l(m)/s(m²), where ρ(Ωm) is the contact resistivity, and l(m) is the contact length in meters.

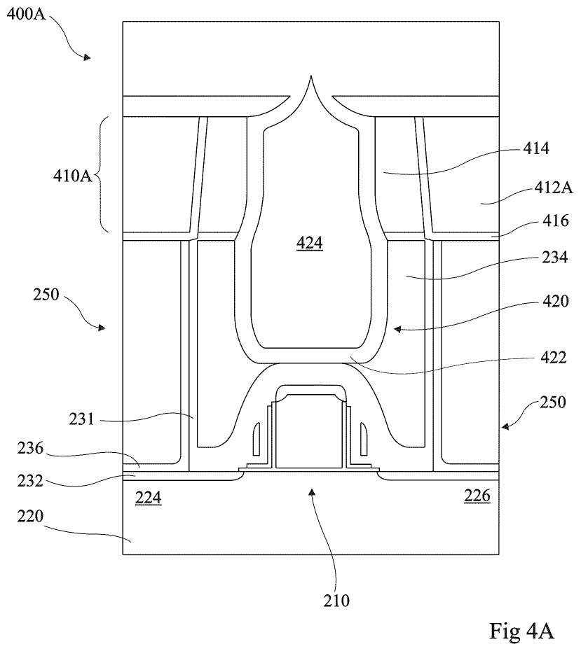

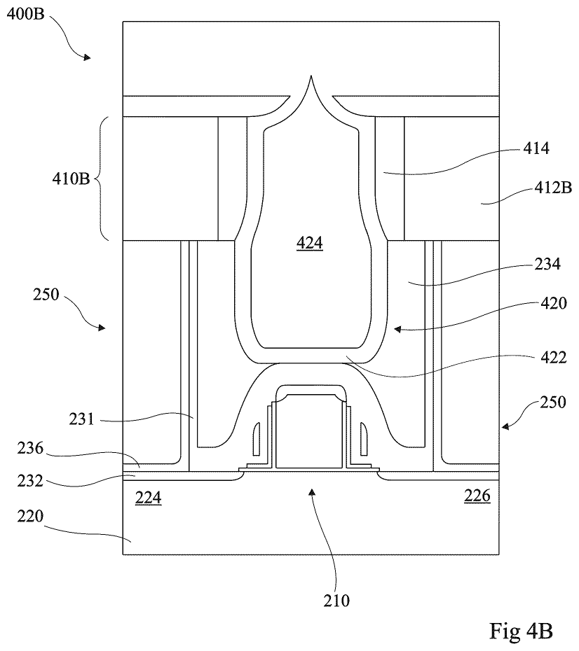

Furthermore, the presence of the dielectric layer on the side walls of the opening allows forming a protective layer for the contact formed in the opening, which can be advantageous, e.g. when an etching step is carried out near the contact. The above is illustrated hereinafter with reference to FIGS. 4A and 4B.

The embodiments can find applications for electronic components used in RF (radio frequency) communication applications, such as RF switch technologies. More particularly for RF switches, it is advantageous to have the dielectric layer as a protective layer, in order to protect conductive structures from possible future etchings, e.g. when adding air cavities between the contacts, or in the case of bringing contacts closer together in order to reduce the surface footprint of the electronic components.

FIG. 4A and FIG. 4B are sectional views schematically representing examples of electronic components 400A, 400B to which the embodiments apply.

The electronic component 400A of FIG. 4A comprises, similarly to the electronic component 200 of FIG. 2E, a MOS transistor 210 and electrical contacts 250 coupled to drain or source 224 and source or drain 226 semiconductor regions of the MOS transistor 210 via a silicide layer 232.

Similarly to the electronic component 200 of FIG. 2E, the MOS transistor 210 has a dielectric region 234 on top in which the contacts 250 are located. The contacts 250 come out onto the silicide layer 232 covering the semiconductor regions 224, 226. A coating layer 231 is positioned on the side walls inside each contact 250. A diffusion barrier layer 236 covers the coating layer 231 and the silicide layer 232.

In FIG. 4A, a first metal level 410A of an interconnection region is represented, the first metal level 410A comprising metal pads 412A made of copper (Cu), each metal pad being connected to a contact 250. The metal pads 412A are insulated by a dielectric material 414, e.g. a silicon oxide containing carbon (SiOC), a silicon phosphide known by the abbreviation PSG (Phospho-Silicon Glass), or a silicon borophosphide known by the abbreviation BPSG (Borophospho-Silicon Glass). An etch stop layer 416, e.g. silicon carbon nitride (SiCN), can be provided before forming the first metal level, in anticipation of etching (of the metal or of the dielectric, depending on the method used), for forming the first metal level 410A in the dielectric material 414 of the interconnection region.

The electronic component 400A of FIG. 4A differs from the electronic component 200 of FIG. 2E mainly in that the dielectric region 234, as well as the dielectric material 414 of the first metal level 410A, are crossed by a gas cavity 420, e.g, an air cavity called “air gap”, substantially centered above the transistor 210. Such a cavity aims to reduce the capacitive effect of the electronic component, more particularly for the RF switch application. For example, the gas cavity 420 comprises an oxide liner 422, e.g. made of SiO₂, enclosing a volume of gas under vacuum 424.

The gas cavity 420 can be formed by using an isotropic chemical etching of the dielectric region 234, as well as of the dielectric material 414. During the etching, the coating layer 231, which is e.g. made of silicon nitride, advantageously makes it possible to stop the etching selectivity, in order to protect the contact 250.

The electronic component 400B of FIG. 4B differs from the electronic component 400A of FIG. 4A mainly in that the first metal level 410B of the interconnection region comprises metal pads 412B of aluminum (Al), instead of copper, and in that same does not include any etch stop layer.

Various embodiments and variants have been described. Those skilled in the art will understand that certain features of these embodiments can be combined and other variants will readily occur to those skilled in the art. In particular, in the embodiments described, the contact is an electrical contact for a MOS transistor, and is formed on a semiconductor region which has a silicide interface layer (silicided region) on top. The semiconductor region is e.g. a source region, or a drain region, or even a gate region. The above is not limiting, since the embodiments described can be applied to any electronic component, e.g. any type of transistor or any type of diode, comprising a semiconductor region intended for being electrically coupled to an electrically conductive connection by means of a contact, the semiconductor region being silicided or non-silicided. Furthermore, in the embodiments described, the contacts have a right circular cylinder shape, i.e. a circular cross-section. The above is not limiting, the embodiments described being applicable to contacts having other shapes, e.g. a cylinder shape which is not necessarily circular and/or right, or a parallelepiped shape, the embodiments making it possible to adapt at least one transverse dimension of the contact.

Finally, the practical implementation of the embodiments and variants described herein is within the capabilities of those skilled in the art based on the functional description provided hereinabove.

What is claimed is:

1. A method for manufacturing a contact on a semiconductor region of an electronic component, the method comprising:
forming a coating layer of dielectric material, with a first thickness, on at least one side wall of an opening crossing through a dielectric region of the electronic component along a longitudinal direction from a first surface of the dielectric region, and opening out at the semiconductor region; and
forming a metal filler layer to fill the opening coated with the coating layer.

2. The method according to claim 1, further comprising:
forming a silicide interface layer comprising an interface between the semiconductor region and the contact; and
after forming the silicide interface layer, forming the opening through the dielectric region, wherein a width of the silicide interface layer is greater than a diameter of the opening.

3. The method according to claim 1, wherein the opening has a fixed cross-section, and the first thickness is determined for adapting an effective cross-section of the contact by reducing the cross-section of the opening.

4. The method according to claim 1, wherein the opening has a circular cylinder shape with a first diameter, the contact having a circular cylinder shape of a second diameter smaller than the first diameter, and the first thickness is determined for adapting the second diameter by reducing the first diameter by at least twice the first thickness.

5. The method according to claim 1, further comprising forming a diffusion barrier layer at a bottom of the opening and laterally in the opening on the coating layer, the formation of the diffusion barrier layer being carried out after forming the coating layer and before forming the filling layer.

6. The method according to claim 1, wherein forming the metal filler layer comprises:
depositing a metal layer from the first surface of the dielectric region; and
removing a portion of the metal layer extending over the openings and the first surface of the dielectric region to make the contact flush with the first surface.

7. The method according to claim 6, wherein removing the portion of the metal layer comprises a chemical mechanical polishing.

8. The method according to claim 1, wherein the dielectric material of the coating layer, or of the layer of dielectric material, is chosen from one or a plurality of materials among: silicon nitride, silicon oxide, silicon oxycarbide, silicon oxycarbonitride, or silicon carbonitride; and/or the metal of the filler layer, or of the metal layer, is chosen among tungsten or copper.

9. The method according to claim 1, wherein the first thickness of the coating layer is greater than or equal to 50 nm, wherein the opening has a diameter in a range 225 to 275 nm.

10. A method for manufacturing a contact on a semiconductor region of an electronic component, the method comprising:
forming a coating layer of dielectric material, with a first thickness, on at least one side wall of an opening crossing through a dielectric region of the electronic component along a longitudinal direction from a first surface of the dielectric region, and opening out at the semiconductor region; and
forming a metal filler layer to fill the opening coated with the coating layer, wherein forming the coating layer comprises:
depositing a layer of dielectric material from the first surface of the dielectric region, at least on the side walls and at a bottom of the opening; and
removing by etching of a portion of the layer of dielectric material located at the bottom of the opening.

11. The method according to claim 10, further comprising:
forming a silicide interface layer comprising an interface between the semiconductor region and the contact; and
after forming the silicide interface layer, forming the opening through the dielectric region, wherein a width of the silicide interface layer is greater than a diameter of the opening.

12. The method according to claim 10, wherein the removing by etching further comprises removing a portion of the dielectric material layer located on the first surface of the dielectric region.

13. The method according to claim 10, wherein the etching is an anisotropic plasma etching and etches the dielectric material layer along the longitudinal direction.

14. The method according to claim 10, wherein the opening has a fixed cross-section, the method further comprising determining the first thickness for adapting an effective cross-section of the contact by reducing the cross-section of the opening.

15. An electronic device comprising:
an electronic component comprising at least one contact on a semiconductor region of the electronic component, each contact being positioned in an opening crossing through a dielectric region of the electronic component along a longitudinal direction from a first surface of the dielectric region, and opening out at the semiconductor region, the contact comprising a coating layer of dielectric material, with a first thickness, extending along at least one side wall of the opening and a filler layer of metal in the opening coated with the coating layer.

16. The electronic device according to claim 15, further comprising a diffusion barrier layer at a bottom of the opening and laterally in the opening between the coating layer and the filler layer.

17. The electronic device according to claim 15, further comprising an air cavity, crossing through an interconnection region of the electronic component and the dielectric region near the contact.

18. The electronic device according to claim 15, wherein the dielectric material of the coating layer, or of the coating layer of dielectric material, is chosen from one or a plurality of materials among: silicon nitride, silicon oxide, silicon oxycarbide, silicon oxycarbonitride, or silicon carbonitride; and/or the metal of the filler layer, or of the metal layer, is chosen among tungsten or copper.

19. The electronic device according to claim 15, wherein the first thickness of the coating layer is greater than or equal to 50 nm.

20. The electronic device according to claim 15, wherein the electronic component comprises a silicide interface layer forming an interface between the semiconductor region and the contact, wherein a width of the silicide interface layer is greater than a diameter of the opening.

21. The electronic device according to claim 15, wherein the opening has a diameter between 225 nm and 275 nm.
